(19) United States
(12) Patent Application Publication
(10) Pub. No.: US 2018/0097485 A1
(43) Pub. Date: Apr. 5, 2018

(54) HPA Bypass Switch

(71) Applicant: SPAWAR Systems Center Pacific, San Diego, CA (US)

(72) Inventors: Sonny Boy C. Reyes, San Diego, CA (US); Jessica G. Lam, San Francisco, CA (US); Bobby Barnes, La Mesa, CA (US); Angelica M. Maldonado, Charleston, SC (US); Tuyen D. Le, San Diego, CA (US); Bernard A. Trumbach, Chula Vista, CA (US); Timothy J. Jasper, Alpine, CA (US)

(73) Assignee: United States of America as represented by Secretary of the Navy, San Diego, CA (US)

(21) Appl. No.: 15/715,507

(22) Filed: Sep. 26, 2017

Related U.S. Application Data
(60) Provisional application No. 62/403,695, filed on Oct. 3, 2016.

(51) Int. Cl. H03F 3/213; H03F 3/193; H04B 1/38

(52) U.S. Cl. CPC H03F 3/213; H03F 3/193; H03F 2200/27; H03F 2200/396; H04B 1/38

(57) ABSTRACT

A switch includes: an HPA bypass switching component that can be in an HPA bypass state and an HPA state and an HPA switching component that can be in the HPA bypass state and the HPA state. When the HPA bypass switching component is in the HPA bypass state, the HPA switching component is in the HPA bypass state. When the HPA bypass switching component is in the HPA bypass state and the transceiver is generating a transceiver transmission signal, the transceiver transmission signal is provided to the antenna and the received transceiver transmission signal is provided to the transceiver. When the HPA bypass switching component is in the HPA state and the high power amplifier is generating an HPA transmission signal, the HPA transmission signal is provided to the antenna and the received HPA signal is provided to the transceiver.

### FEDERALLY-SPONSORED RESEARCH AND DEVELOPMENT

The United States Government has ownership rights in this invention. Licensing inquiries may be directed to Office of Research and Technical Applications, Space and Naval Warfare Systems Center, Pacific, Code 36000, San Diego, Calif., 92152; telephone (619) 553-5118; email: ssc_pac_t2@navy.mil. Reference Navy Case No. 103,442.

### BACKGROUND OF THE INVENTION

Embodiments of the invention relate to a system and method for transmitting and receiving signals.

There are multiple ways in which signals can be received and transmitted. One such way is by a conventional transceiver and another is by a high powered amplifier (HPA). An HPA may be used when it is necessary to improve likelihood of receipt of signals when operating in environment that hinders the use of a conventional transceiver. For example, a ship traveling on the ocean may need to send signals to locations on land; the use of an HPA can help ensure successful receipt of the signal by a receiver. When the operating environment is unlikely to corrupt a transmitted signal, such as when a ship traveling on the ocean desires to send a signal to a nearby ship, those signals may be transmitted by a standard transceiver.

FIGS. 1A-B illustrate a prior art system and method for sending signals.

As shown in the figures, system 100 includes an antenna 102, a notch filter assembly 104, a radiofrequency (RF) limiter 106, an HPA 108, a transceiver 110, a port 112, a port 114, a port 116, a port 118, and a port 120.

Transceiver 110 is connected to port 120. Transceiver 110 may be any conventional device or system that is capable of sending or receiving signals. Port 120 may be any device or system that can connect to transceiver 110 and provide another connection to communication channel 126.

HPA 108 is connected to port 116. HPA 108 may be any conventional device or system that is capable of amplifying signals such that the signals are less subject to corruption than if the signals were sent via a conventional transceiver like transceiver 110. Port 116 may be any device or system that can connect to HPA 108 and provide another connection to communication channel 124.

RF limiter 106 is connected to port 118 and notch filter assembly 104. RF limiter 106 may be any device or system that blocks excess reflection attributable to an open or short in the circuit. Port 118 may be any device or system that can connect to RF limiter 106 and provide another connection to communication channel 126. When communication channel 126 is active, RF limiter 106 is in communication with transceiver 110.

Notch filter assembly 104 is connected to ports 114 and 112 and RF limiter 106. Notch filter assembly 104 may be any device or system that can remove unwanted frequencies or frequency bands from the signals generated by HPA 108 or transceiver 110. Port 114 may be any device or system that can connect to notch filter assembly 104 and provide another connection to communication channel 124. When communication channel 124 is active, notch filter assembly 104 is in communication with HPA 108. Port 112 may be any device or system that can connect to notch filter assembly 104 and provide a connection to communication channel 122.

Antenna 102 is connected to port 112 via communication channel 122. Antenna 102 may be any device or system that can convert electrical power into radio waves, and then broadcast the radio waves.

With reference to FIG. 1A, and for purposes of explanation, system 100 may be located on a ship at sea. HPA 108 normally amplifies the signal from the transceiver 110, received via cable 111. The output from HPA port 116 is transmitted through port 114 to notch filter 104.

To send a signal to the desired location the signal may be amplified, so HPA 108 is connected to notch filter assembly 104. This connection is denoted by the solid line of communication channel 124. The signal is then generated by HPA 108 and proceeds through port 116, communication channel 124, port 114, notch filter assembly 104, port 112, communication channel 122, and antenna 102 to broadcast the signal to the desired location.

With reference to FIG. 1B, it should be noted that HPA 108 is used during normal operations. The by-pass configuration shown in FIG. 1B is utilized when the HPA 108 is not working properly or when the ship is in port or near the shore after a future frequency remapping feature is implemented in transceiver 110 for which the HPA 108 is not compatible. To send a signal to the other ship and minimize the possibility of broadcasting a signal that may be intercepted, HPA 108 is not used. Port 116 is coupled to a dummy load 128 via communication channel 127. Transceiver 110 must then be connected to the notch filter assembly via port 114 through communication channel 125 while port 116 is coupled to a dummy load 128 via communication channel 127. The RF limiter 106 is also coupled to an RF short 130 via communication channel 123. The signal is generated by transceiver 110 and proceeds through port 120, communication channel 125, port 114, notch filter assembly 104, port 112, communication channel 122, and antenna 102 to broadcast the signal to the desired location. When operating in HPA bypass, the transceiver signal is not provided to the HPA 108, but is provided to the power amplifier (not shown) in the transceiver 110, then to port 120, cable 125 and port 114.

Over time, it becomes cumbersome to continue physically connecting and disconnecting HPA 108 and transceiver 110 to send signals to different physical locations. Additionally, if a mistake is made and one of HPA 108 or transceiver 110 is not properly disconnected, the system may malfunction or send signals to an unintended location. Thus, a system and method is needed to easily switch between an HPA and a transceiver without physically disconnecting and reconnecting for each use.

### SUMMARY OF THE INVENTION

An aspect of the present invention is drawn to a switch for use with an antenna, a transceiver, a high power amplifier (HPA). The switch includes: an HPA bypass switching component that can be in an HPA bypass state and an HPA state, and an HPA switching component that can be in the HPA bypass state and the HPA state. When the HPA bypass switching component is in the HPA bypass state, the HPA switching component is in the HPA bypass state. When the HPA bypass switching component is in the HPA state, the HPA switching component is in the HPA state. When the HPA bypass switching component is in the HPA bypass state and the transceiver is generating a transceiver transmission signal, the transceiver transmission signal is provided to the antenna and the received transceiver transmission signal is provided to the transceiver. When the HPA bypass switching component is in the HPA state and the high power amplifier is generating an HPA transmission signal, the HPA transmission signal is provided to the antenna and the received HPA signal is provided to the transceiver.

### BRIEF DESCRIPTION OF THE DRAWINGS

The accompanying drawings, which are incorporated in and form a part of the specification, illustrate example embodiments and, together with the description, serve to explain the principles of the invention. In the drawings:

FIGS. 1A-B illustrate a prior art system and method for sending signals;

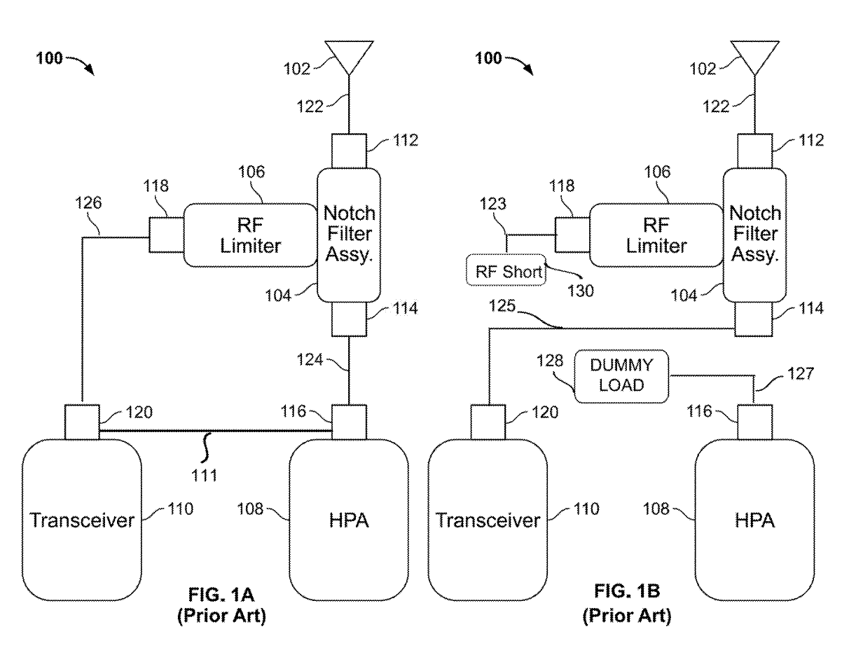

FIG. 2 illustrates a method by which signals may be transmitted via transceiver or HPA according to aspects of the present invention;

FIG. 3A illustrates a mechanical system to switch between a transceiver and an HPA in the transceiver state according to aspects of the present invention;

FIG. 3B illustrates a mechanical system to switch between a transceiver and an HPA in the HPA state according to aspects of the present invention;

FIG. 4A illustrates an electrical system to switch between a transceiver and an HPA in the transceiver state according to aspects of the present invention; and

FIG. 4B illustrates an electrical system to switch between a transceiver and an HPA in the HPA state according to aspects of the present invention.

### DETAILED DESCRIPTION OF THE EMBODIMENTS

The present invention provides a system and method to switch between an HPA and a transceiver without physically disconnecting and reconnecting for each use.

Embodiments of the present invention provide a switch that can be manipulated by a user. When the user manipulates the switch to an HPA bypass state, an HPA bypass switching component connects a transceiver with an antenna so the transceiver can transmit and/or receive signals. In the HPA bypass state, the HPA connected to the system is unable to send signals. When the user manipulates the switch to an HPA state, the HPA bypass switching component enables the transceiver only to receive signals, and the HPA switching component connects an HPA with the antenna so the HPA can transmit signals. In some embodiments, the switch is a mechanical switch that mechanically changes connections when moving between the HPA bypass state and the HPA state. In other embodiments, the switch is an electrical switch that electrically changes connections when moving between the HPA bypass state and the HPA state.

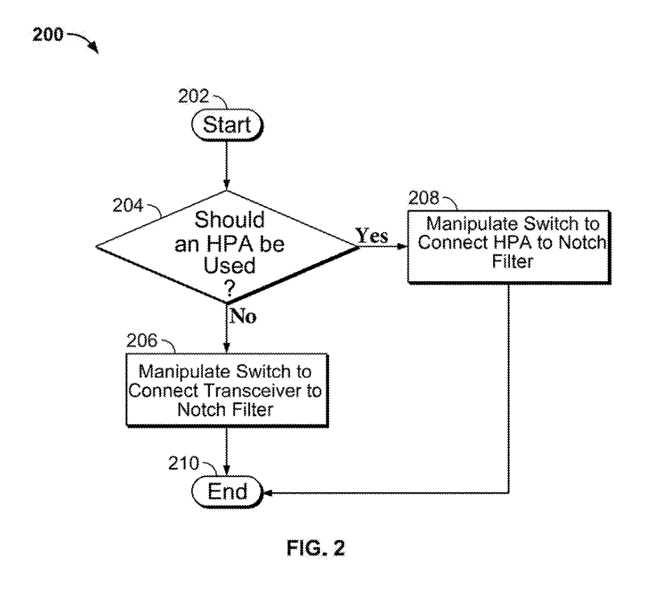

Aspects of the present invention will now be discussed with reference to FIGS. 2-4.

FIG. 2 illustrates a method by which signals may be transmitted via transceiver or HPA according to aspects of the present invention.

As shown in the figure, method 200 starts (202) and a user determines if an HPA should be used for a communication (204).

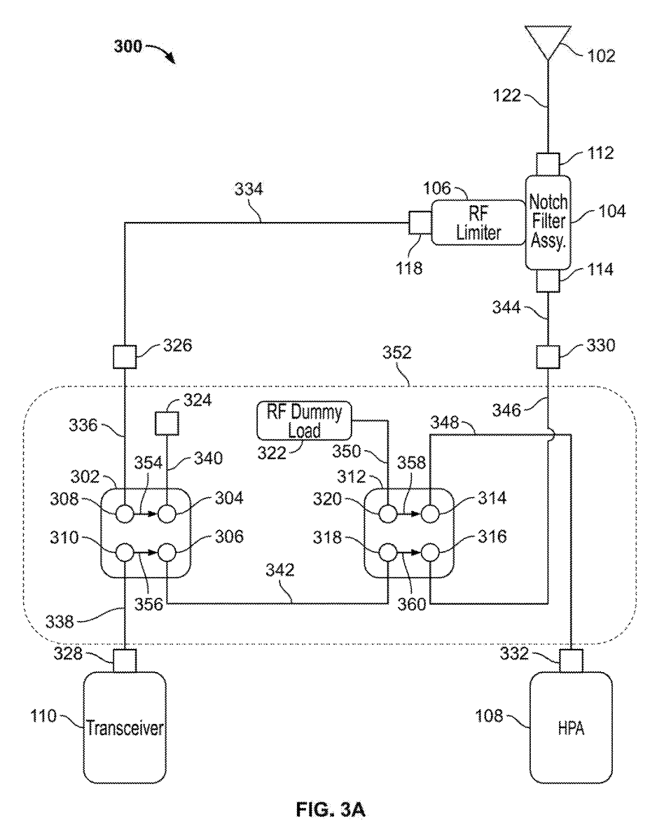

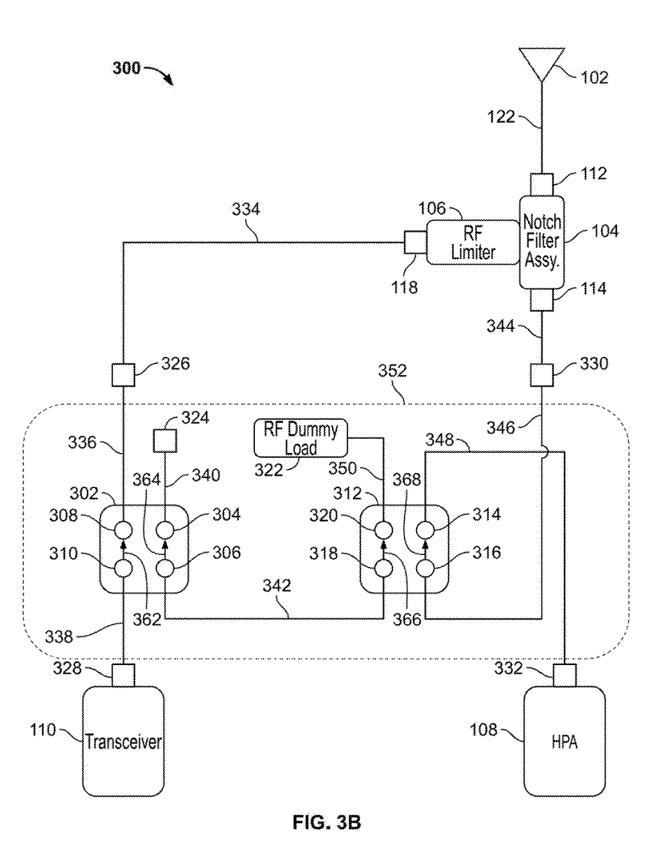

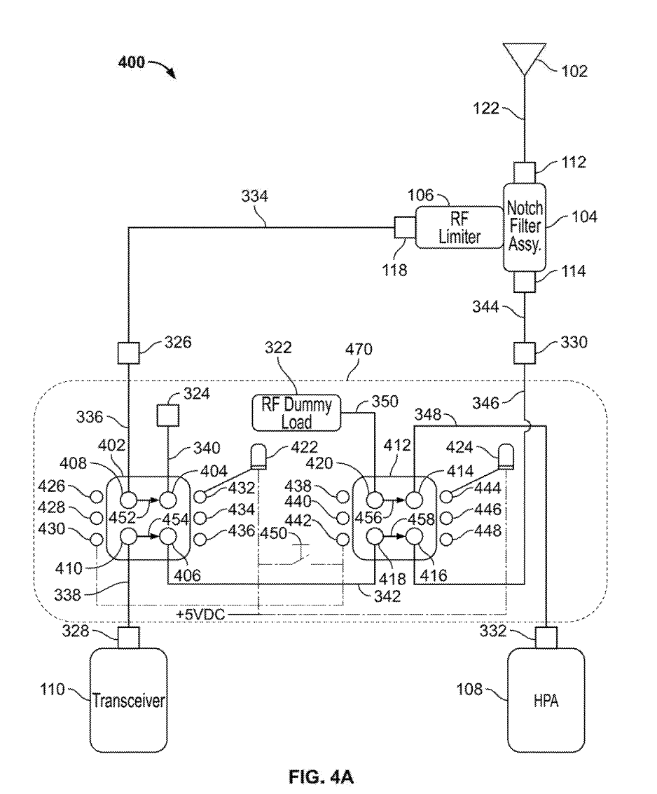

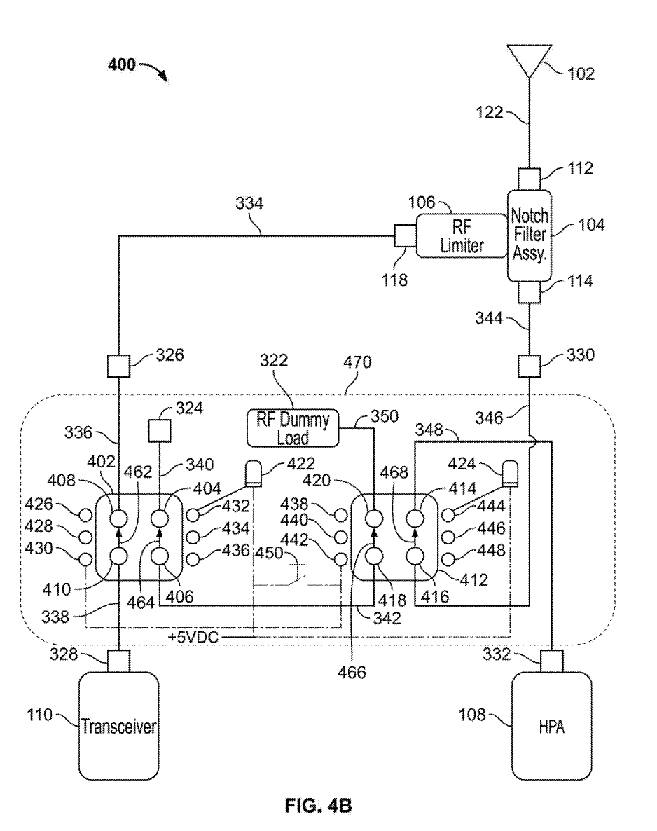

For purposes of explanation, the user may be on a ship on the ocean, far from land. The HPA is normally used for all communications. There may be other ships in the vicinity of the user's ship which could lead to concern about corruption of the signal. Therefore, the user decides that the best way to send the desired signal is to use the HPA (YES at 204) so the user manipulates a switch to connect the HPA to the notch filter (208). If “No”, then the transceiver is coupled to the notch filter (206). The process by which the HPA and transceiver are connected to the notch filter will be further described with reference to FIGS. 3A and 4A.

FIG. 3A illustrates a mechanical system to switch between a transceiver and an HPA in the transceiver state according to aspects of the present invention.

As shown in the figure, a mechanical system 300 includes a mechanical switch 352, a port 326, a port 328, a port 330, and a port 332. Mechanical switch 352 further includes an HPA bypass switching component 302, an HPA switching component 312, a RF dummy load 322, and a RF short 324. HPA bypass switching component 302 further includes nodes 304-310. HPA switching component 312 further includes nodes 314-320.

Mechanical switch 352 may be any device or system that provides the user the ability to physically switch the operation of mechanical system 300 between two different states. Non-limiting examples of mechanical switch 352 include levers and dials.

HPA bypass switching component 302 and HPA switching component 312 may be any device or system that provides the ability to route signals in two different ways, depending on the state of mechanical switch 352.

Nodes 304-310 are junctions within HPA bypass switching component 302. The connections between nodes 304-310 may be changed depending on the state of mechanical switch 352. Nodes 314-320 are junctions within HPA switching component 312. The connections between nodes 314-320 may be changed depending on the state of mechanical switch 352.

Referring back to the example of a user on a ship, the user desires to send a signal using transceiver 110. To do so, the user must make sure mechanical switch 352 is in the state that will allow transceiver 110 to send a signal to antenna 102 and prevent HPA 108 from sending a signal to antenna 102. The user will therefore manipulate mechanical switch 352 to the HPA bypass state, which puts HPA bypass switching component 302 in the HPA bypass state. Switching to this state causes nodes 308 and 304 to connect via communication channel 354, nodes 310 and 306 to connect via communication channel 356, nodes 316 and 318 to connect via communication channel 360, and nodes 314 and 320 to connect via communication channel 358.

With HPA bypass switching component 302 in the HPA bypass state, transceiver 110 generates a signal and sends the signal to port 328, which forwards the signal to node 310 via communication channel 338. The signal then travels from node 310 to node 306 via communication channel 356, and then to node 318 via communication channel 342. The signal is then passed from node 318 to node 316 via communication channel 360. From node 316, the signal travels to port 330 via communication channel 346, and then to port 114 via communication channel 344. The signal then passes through notch filter assembly 104, and notch filter assembly 104 assures that the signal is sent across the desired frequency bands by filtering out the unwanted bands. The filtered signal is sent to port 112, and then the signal travels to antenna 102 via communication channel 122, and finally the signal is broadcast from antenna 102.

In some instances, during operation some or all of the signals may be inadvertently diverted through RF limiter 106. In these instances, the signal will then pass through port 118 and be sent to port 326 via communication channel 334, then to node 308 via communication channel 336. The signal will then be sent to node 304 via communication channel 354, and then go to RF short 324 via communication channel 340. By routing the signal in this manner, the signal is shorted out to bypass the RF limiter and reduce the attenuation of the signal path.

In some instances the signal sent from HPA 108 is sent to port 332 and then travels to node 314 via communication channel 348. The signal then travels to node 320 via communication channel 358, and then to RF dummy load 322 via communication channel 350. In this configuration, RF dummy load 322 ensures that HPA 108 will not be damaged by transmitting into an open circuit.

In an alternate embodiment, the system used may be electrically based. This will be further described with reference to FIG. 4A.

FIG. 4A illustrates an electrical system to switch between a transceiver and an HPA in the transceiver state according to aspects of the present invention.

As shown in the figure, an electrical system 400 includes an electrical switch 470. Electrical switch 470 further includes an HPA bypass switching component 402, an HPA switching component 412, a light emitting diode (LED) 422, a LED 424, and a toggle 450. HPA bypass switching component 402 further includes nodes 404-410, an input voltage 426, a ground 428, a logic input 430, an LED connection 432, and a ground 434. HPA switching component 412 further includes nodes 414-420, an input voltage 438, a ground 440, a logic input 442, an LED connection 444, and a ground 446.

Electrical switch 470 may be any device or system that provides the user the ability to electrically switch the operation of electrical system 400 between two different states. Non-limiting examples of electrical switch 470 include push buttons, toggles, and sliders.

HPA bypass switching component 402 and HPA switching component 412 may be any device or system that provides the ability to route signals in two different ways, depending on the state of electrical switch 470.

LEDs 422 and 424 may be any conventional light emitting diodes that emit a light when connected to a power source.

Toggle 450 may be any device or system that can open or close electrical connections to control the state of electrical switch 470.

Nodes 404-410 are junctions within HPA bypass switching component 402. The connections between nodes 404-410 may be changed depending on the state of electrical switch 470. Nodes 414-420 are junctions within HPA switching component 412. The connections between nodes 414-420 may be changed depending on the state of electrical switch 470.

Input voltages 426 and 438 provide power to HPA bypass switching component 402 and HPA switching component 412, respectfully. Ground 428 and ground 434 provide electrical grounding for HPA bypass switching component 402. Ground 440 and ground 446 provide electrical grounding for HPA switching component 412. Logic input 430 provides information to HPA bypass switching component 402 detailing how nodes 404-410 are connected based on the state of electrical switch 470. Logic input 442 provides information to HPA switching component 412 detailing how nodes 414-420 are connected based on the state of electrical switch 470. LED connections 432 and 444 connect to LEDs 422 and 424, respectively, and allow LEDs 422 and 424 to be illuminated based on the state of electrical switch 470.

With reference again to the example of a user on a ship, in order to send a signal using transceiver 110 using system 400, the user must make sure electrical switch 470 is in the state that will allow transceiver 110 to send a signal to antenna 102 and prevent HPA 108 from sending a signal to antenna 102. The user will therefore manipulate toggle 450 to the HPA bypass state, which puts HPA bypass switching component 402 in the HPA bypass state. The user is notified that system 400 is in this state because LED 422 will be illuminated and LED 424 will not be illuminated. Switching to this state causes nodes 408 and 404 to connect via communication channel 452, nodes 410 and 406 to connect via communication channel 454, nodes 416 and 418 to connect via communication channel 458, and nodes 414 and 420 to connect via communication channel 456.

With HPA bypass switching component 402 in the HPA bypass state, transceiver 110 generates a signal and sends the signal to port 328, which forwards the signal to node 410 via communication channel 338. The signal then travels from node 410 to node 406 via communication channel 454, and then to node 418 via communication channel 342. The signal is then passed from node 418 to node 416 via communication channel 458. From node 416, the signal travels to port 330 via communication channel 346, and then to port 114 via communication channel 344. The signal then passes through notch filter assembly 104, and notch filter assembly 104 assures that the signal is sent across the desired frequency bands by filtering out the unwanted bands. The filtered signal is sent to port 112, and then the signal travels to antenna 102 via communication channel 122, and finally the signal is broadcast from antenna 102.

In some instances, during operation some or all of the signals may be inadvertently diverted through RF limiter 106. In these instances, the signal will then pass through port 118 and be sent to port 326 via communication channel 334, then to node 408 via communication channel 336. The signal will then be sent to node 404 via communication channel 452, and then go to RF short 324 via communication channel 340. By routing the signal in this manner, the signal is shorted out to bypass the RF limiter and reduce the attenuation of the signal.

In some instances, the signal sent from HPA 108 is sent to port 332 and then travels to node 414 via communication channel 348. The signal then travels to node 420 via communication channel 456, and then to RF dummy load 322 via communication channel 350. In this configuration, RF dummy load 322 ensures that HPA 108 will not be damaged by transmitting into an open circuit.

Referring back to FIG. 2, after the switch enables the transceiver (206) and the signal is sent, method 200 ends (210).

In another embodiment, the user may determine that instead of sending a signal to a nearby ship, a signal must be sent a much longer distance to a base on land. Because the signal must travel a long distance, the user knows the signal must be amplified to travel the desired distance and reach the intended recipient. Therefore, the user decides that the best way to send the desired signal is to use an HPA (NO at 204) so the user must enable the HPA (208). The process by which the HPA is enabled will be further described with reference to FIGS. 3B and 4B.

FIG. 3B illustrates a mechanical system to switch between a transceiver and an HPA in the HPA state according to aspects of the present invention.

The user desires to send a signal using HPA 108. To do so, the user must make sure mechanical switch 352 is in the state that will allow HPA 108 to send a signal to antenna 102 and prevent transceiver 110 from sending a signal to antenna 102. The user will therefore manipulate mechanical switch 352 to the HPA state, which puts HPA switching component 312 in the HPA bypass state. Switching to this state causes nodes 308 and 310 to connect via communication channel 362, nodes 302 and 306 to connect via communication channel 364, nodes 316 and 314 to connect via communication channel 368, and nodes 318 and 320 to connect via communication channel 366.

With HPA switching component 312 in the HPA bypass state, HPA 108 generates a signal and sends the signal to port 332, which forwards the signal to node 314 via communication channel 348. The signal then travels from node 314 to node 316 via communication channel 368. From node 316, the signal travels to port 330 via communication channel 346, and then to port 114 via communication channel 344. The signal then passes through notch filter assembly 104, and notch filter assembly 104 assures that the signal is sent across the desired frequency bands by filtering out the unwanted bands. The filtered signal is sent to port 112, and then the signal travels to antenna 102 via communication channel 122, and finally the signal is broadcast from antenna 102.

In some instances, during operation some or all of the signals may be inadvertently diverted through RF limiter 106. In these instances, the signal will then pass through port 118 and be sent to port 326 via communication channel 334, then to node 308 via communication channel 336. The signal will then be sent to node 310 via communication channel 362, and then go to port 328 via communication channel 338. The signal will then reach transceiver 110. Because transceiver 110 is operable to both transmit and receive signals, it can receive the signal sent by HPA 108. Receipt of the signal by transceiver 110 will notify the user that the signal inadvertently was sent through the RF limiter instead of to antenna 102.

In addition, in this state RF dummy load 322 is connected to node 320 via communication channel 350, and node 320 is connected to node 318 via communication channel 366. Node 318 is connected to node 306 via communication channel 342, and node 318 connects to node 304 via communication channel 364. Node 304 is then connected to RF short 324 via communication channel 340. RF dummy load 322 is therefore connected to RF short 324, preventing any damage to HPA bypass switching component 302 and HPA switching component 312 in this configuration.

In an alternate embodiment, the system used may be electrically based. This will be further described with reference to FIG. 4B.

FIG. 4B illustrates an electrical system to switch between a transceiver and an HPA in the HPA state according to aspects of the present invention.

In order to send a signal using HPA 108 using system 400, the user must make sure electrical switch 470 is in the state that will allow HPA 108 to send a signal to antenna 102 and prevent transceiver 110 from sending a signal to antenna 102. The user will therefore manipulate toggle 450 to the HPA state, which puts HPA switching component 412 in the HPA bypass state. The user is notified that system 400 is in this state because LED 424 will be illuminated and LED 422 will not be illuminated. Switching to this state causes nodes 408 and 410 to connect via communication channel 462, nodes 404 and 406 to connect via communication channel 464, nodes 420 and 418 to connect via communication channel 466, and nodes 414 and 416 to connect via communication channel 468.

With HPA switching component 412 in the HPA bypass state, HPA 108 generates a signal and sends the signal to port 332, which forwards the signal to node 414 via communication channel 348. The signal then travels from node 414 to node 416 via communication channel 468. From node 416, the signal travels to port 330 via communication channel 346, and then to port 114 via communication channel 344. The signal then passes through notch filter assembly 104, and notch filter assembly 104 assures that the signal is sent across the desired frequency bands by filtering out the unwanted bands. The filtered signal is sent to port 112, and then the signal travels to antenna 102 via communication channel 122, and finally the signal is broadcast from antenna 102.

In some instances, during operation some or all of the signals may be inadvertently diverted through RF limiter 106. In these instances, the signal will then pass through port 118 and be sent to port 326 via communication channel 334, then to node 408 via communication channel 336. The signal will then be sent to node 410 via communication channel 462, and then go to port 328 via communication channel 338. The signal will then reach transceiver 110. Because transceiver 110 is operable to both transmit and receive signals, it can receive the signal sent by HPA 108. Receipt of the signal by transceiver 110 will notify the user that the signal inadvertently was sent through the RF limiter instead of to antenna 102.

In addition, in this state RF dummy load 322 is connected to node 420 via communication channel 350, and node 420 is connected to node 418 via communication channel 466. Node 418 is connected to node 406 via communication channel 342, and node 406 connects to node 404 via communication channel 464. Node 404 is then connected to RF short 324 via communication channel 340. RF dummy load 322 is therefore connected to RF short 324, preventing any damage to HPA bypass switching component 402 and HPA switching component 412 in this configuration.

Referring back to FIG. 2, after the switch enables the HPA (S208) and the signal is sent, method 200 ends (S210).

In summary, conventional methods of switching between systems to send signals via a transceiver or an HPA are cumbersome and time consuming. Embodiments of the present invention address those issues by providing a switch that can be manipulated by a user to make the transition between systems much easier. When the user manipulates the switch to an HPA bypass state, an HPA bypass switching component connects a transceiver with an antenna so the transceiver can transmit and/or receive signals. In the HPA bypass state, the HPA connected to the system is unable to send signals. When the user manipulates the switch to an HPA state, the HPA bypass switching component enables the transceiver only to receive signals, and the HPA switching component connects an HPA with the antenna so the HPA can transmit signals. In some embodiments, the switch is a mechanical switch that mechanically changes connections when moving between the HPA bypass state and the HPA state. In other embodiments, the switch is an electrical switch that electrically changes connections when moving between the HPA bypass state and the HPA state. Providing this system makes it easier and faster to change between sending signals via a transceiver and an HPA.

The foregoing description of various preferred embodiments have been presented for purposes of illustration and description. It is not intended to be exhaustive or to limit the invention to the precise forms disclosed, and obviously many modifications and variations are possible in light of the above teaching. The example embodiments, as described above, were chosen and described in order to best explain the principles of the invention and its practical application to thereby enable others skilled in the art to best utilize the invention in various embodiments and with various modifications as are suited to the particular use contemplated. It is intended that the scope of the invention be defined by the claims appended hereto.

What is claimed as new and desired to be protected by Letters Patent of the United States is:

1. A switch for use with an antenna, a transceiver, a high power amplifier, the transceiver being operable to generate a transceiver transmission signal, to receive a received transceiver transmission signal, and to receive a received HPA signal, the received transceiver transmission signal being associated with the generated transceiver transmission signal, the high power amplifier being operable to generate an HPA transmission signal when the transceiver is not generating a transceiver transmission signal, the received HPA signal being associated with the HPA transmission signal, said switch comprising:
an HPA bypass switching component operable to be in an HPA bypass state and an HPA state;
an HPA switching component operable to be in the HPA bypass state and the HPA state,
wherein when said HPA bypass switching component is in the HPA bypass state, said HPA switching component is in the HPA bypass state,
wherein when said HPA bypass switching component is in the HPA state, said HPA switching component is in the HPA state,
wherein when said HPA bypass switching component is in the HPA bypass state and the transceiver is generating the transceiver transmission signal, the transceiver transmission signal is provided to the antenna and the received transceiver transmission signal is provided to the transceiver, and
wherein when said HPA bypass switching component is in the HPA state and the high power amplifier is generating the HPA transmission signal, the HPA transmission signal is provided to the antenna and the received HPA signal is provided to the transceiver.

2. The switch of claim 1 for additional use with an RF limiter and a notch filter electrically connected to the antenna and to the RF limiter, said switch further comprising:
an antenna output port electrically connected to said HPA bypass switching component and operable to be electrically connected to the RF limiter;
an HPA output port electrically connected to said HPA switching component and operable to be electrically connected to the notch filter;
an antenna input port electrically connected to said HPA bypass switching component and operable to be electrically connected to the transceiver; and
an HPA input port electrically connected to said HPA switching component and operable to be electrically connected to the high power amplifier.

3. The switch of claim 2,
wherein said HPA bypass switching component comprises an HPA bypass switching component antenna input port, an HPA bypass switching component connection port and an HPA bypass switching component output port, and
wherein said HPA switching component comprises an HPA switching component HPA input port, an HPA switching component connection port and an HPA switching component output port.

4. The switch of claim 3,
wherein said HPA bypass switching component antenna input port is electrically connected to said antenna input port,
wherein said HPA bypass switching component connection port is electrically connected to said HPA switching component connection port,
wherein said HPA bypass switching component output port is electrically connected to said antenna output port,
wherein said HPA switching component HPA input port is electrically connected to said HPA input port, and
wherein said HPA switching component output port is electrically connected to said HPA output port.

5. The switch of claim 4, further comprising:
an RF short; and
an RF dummy load,
wherein said HPA bypass switching component further comprises an HPA bypass switching component RF short port electrically connected to said RF short, and
wherein said HPA switching component further comprises and HPA switching component dummy load port electrically connected to said RF dummy load.

6. The switch of claim 5,
wherein when said HPA bypass switching component is in the HPA bypass state, said HPA bypass switching component antenna input port is additionally electrically connected to said HPA bypass switching component output port, said HPA bypass switching component connection port is additionally electrically connected to said HPA bypass switching component RF short port, said HPA switching component HPA input port is additionally electrically connected to said HPA switching component output port and said HPA switching component connection port is additionally electrically connected to said HPA switching component dummy load port, and
wherein when said HPA bypass switching component is in the HPA state, said HPA bypass switching component antenna input port is additionally electrically connected to said HPA bypass switching component connection port, said HPA bypass switching component output port is electrically connected to said HPA bypass switching component RF short port, said HPA switching component HPA input port is electrically connected to said HPA switching component dummy load port and said HPA switching component connection port is additionally electrically connected to said HPA switching component output port.

7. The switch of claim 6, wherein each of HPA bypass switching component antenna input port, said HPA bypass switching component connection port, said HPA bypass switching component output port, said HPA switching component HPA input port, said HPA switching component connection port and said HPA switching component output port comprises a coaxial cable port.

8. The switch of claim 7, wherein said HPA bypass switching component comprises a mechanical switching component.

9. The switch of claim 7, wherein said HPA bypass switching component comprises an electronic switching component.

10. The switch of claim 2, wherein when said HPA bypass switching component is in the HPA state, said HPA bypass switching component is electrically connected to said HPA switching component.

11. The switch of claim 10,
wherein said HPA bypass switching component comprises an HPA bypass switching component antenna input port, an HPA bypass switching component connection port and an HPA bypass switching component output port, and
wherein said HPA switching component comprises an HPA switching component HPA input port, an HPA switching component connection port and an HPA switching component output port.

12. The switch of claim 11,
wherein said HPA bypass switching component antenna input port is electrically connected to said antenna input port,
wherein said HPA bypass switching component connection port is electrically connected to said HPA switching component connection port,
wherein said HPA bypass switching component output port is electrically connected to said antenna output port,
wherein said HPA switching component HPA input port is electrically connected to said HPA input port, and
wherein said HPA switching component output port is electrically connected to said HPA output port.

13. The switch of claim 12, further comprising:
an RF short; and
an RF dummy load,
wherein said HPA bypass switching component further comprises an HPA bypass switching component RF short port electrically connected to said RF short, and
wherein said HPA switching component further comprises and HPA switching component dummy load port electrically connected to said RF dummy load.

14. The switch of claim 13,
wherein when said HPA bypass switching component is in the HPA bypass state, said HPA bypass switching component antenna input port is additionally electrically connected to said HPA bypass switching component output port, said HPA bypass switching component connection port is additionally electrically connected to said HPA bypass switching component RF short port, said HPA switching component HPA input port is additionally electrically connected to said HPA switching component output port and said HPA switching component connection port is additionally electrically connected to said HPA switching component dummy load port, and
wherein when said HPA bypass switching component is in the HPA state, said HPA bypass switching component antenna input port is additionally electrically connected to said HPA bypass switching component connection port, said HPA bypass switching component output port is electrically connected to said HPA bypass switching component RF short port, said HPA switching component HPA input port is electrically connected to said HPA switching component dummy load port and said HPA switching component connection port is additionally electrically connected to said HPA switching component output port.

15. The switch of claim 14, wherein each of HPA bypass switching component antenna input port, said HPA bypass switching component connection port, said HPA bypass switching component output port, said HPA switching component HPA input port, said HPA switching component connection port and said HPA switching component output port comprises a coaxial cable port.

16. The switch of claim 15, wherein said HPA bypass switching component comprises a mechanical switching component.

17. The switch of claim 15, wherein said HPA bypass switching component comprises an electronic switching component.

18. The switch of claim 1, wherein said HPA bypass switching component comprises one of the group consisting of a mechanical switching component and an electronic switching component.

19. A switch for use with an antenna, a transceiver, a high power amplifier, the transceiver being operable to generate a transceiver transmission signal, to receive a received transceiver transmission signal, and to receive a received HPA signal, the received transceiver transmission signal being associated with the generated transceiver transmission signal, the high power amplifier being operable to generate an HPA transmission signal when the transceiver is not generating a transceiver transmission signal, the received HPA signal being associated with the HPA transmission signal, said switch comprising:
an HPA bypass switching component operable to be in an HPA bypass state and an HPA state, the HPA bypass switching component having a connection port, an RF short port, an antenna input port and an output port;
an HPA switching component operable to be in the HPA bypass state and the HPA state, the HPA switching component having a dummy load port,
wherein when said HPA bypass switching component is in the HPA bypass state, said HPA switching component is in the HPA bypass state,
wherein when said HPA bypass switching component is in the HPA state, said HPA switching component is in the HPA state,
wherein when said HPA bypass switching component is in the HPA bypass state and the transceiver is generating the transceiver transmission signal, the transceiver transmission signal is provided to the antenna and the received transceiver transmission signal is provided to the transceiver,
when said HPA bypass switching component is in the HPA state and the high power amplifier is generating the HPA transmission signal, the HPA transmission signal is provided to the antenna and the received HPA signal is provided to the transceiver,
wherein when said HPA bypass switching component is in the HPA bypass state, said HPA bypass switching component antenna input port is additionally electrically connected to said HPA bypass switching component output port, said HPA bypass switching component connection port is additionally electrically connected to said HPA bypass switching component RF short port, said HPA switching component HPA input port is additionally electrically connected to said HPA switching component output port and said HPA switching component connection port is additionally electrically connected to said HPA switching component dummy load port, and
wherein when said HPA bypass switching component is in the HPA state, said HPA bypass switching component antenna input port is additionally electrically connected to said HPA bypass switching component connection port, said HPA bypass switching component output port is electrically connected to said HPA bypass switching component RF short port, said HPA switching component HPA input port is electrically connected to said HPA switching component dummy load port and said HPA switching component connection port is additionally electrically connected to said HPA switching component output port.

20. A method of transmitting with an antenna, a transceiver, a high power amplifier, the transceiver being operable to generate a transceiver transmission signal, to receive a received transceiver transmission signal, and to receive a received HPA signal, the received transceiver transmission signal being associated with the generated transceiver transmission signal, the high power amplifier being operable to generate an HPA transmission signal when the transceiver is not generating a transceiver transmission signal, the received HPA signal being associated with the HPA transmission signal, said method comprising:
placing an HPA bypass switching component and an HPA switching component into an HPA bypass state,
generating, via the transceiver, the transceiver transmission signal;
providing, via the HPA bypass switching component and then via the HPA switching component, the transceiver transmission signal to the antenna;
receiving, via the antenna, the transceiver transmission signal;
providing, via the HPA bypass switching component, the transceiver transmission signal to the transceiver;
placing the HPA bypass switching component and the HPA switching component into an HPA state;
generating, via the high power amplifier, the HPA transmission signal;
providing, via the HPA switching component, the HPA transmission signal to the antenna;
receiving, via the antenna, the received HPA signal;
providing, via the HPA bypass switching component, the received HPA signal to the transceiver.
